(19) United States
(12) Patent Application Publication
(10) Pub. No.: US 2025/0089425 A1
(43) Pub. Date: Mar. 13, 2025

(54) DISPLAY APPARATUS AND METHOD OF MANUFACTURING THE DISPLAY APPARATUS

(71) Applicant: SAMSUNG ELECTRONICS CO., LTD., Suwon-si (KR)

(72) Inventors: Kyungwook HWANG, Suwon-si (KR); Jungwoon Shin, Hwaseong-si (KR); Keunsik Lee, Hwaseong-si (KR); Junsik Hwang, Suwon-si (KR); Hakyeol Kim, Hwaseong-si (KR); Sanghoon Song, Suwon-si (KR); Eungyeong Lee, Hwaseong-si (KR); Dongho Kim, Suwon-si (KR); Youngtek Oh, Suwon-si (KR)

(73) Assignee: SAMSUNG ELECTRONICS CO., LTD., Suwon-si (KR)

(21) Appl. No.: 18/883,770

(22) Filed: Sep. 12, 2024

(30) Foreign Application Priority Data
Sep. 12, 2023 (KR) 10-2023-0121382

(51) Int. Cl. H01L 33/62; H01L 25/075; H01L 33/00

(52) U.S. Cl. CPC H10H 20/857; H01L 25/0753; H10H 20/01; H10H 20/032; H10H 20/0364

(57) ABSTRACT

Provided is a display apparatus including a display substrate, a first pad and a second pad, a first electrode on the first pad, a multilayer semiconductor layer including a first-type semiconductor layer, an active layer, and a second-type semiconductor layer on the first electrode, an insulating layer on the display substrate and adjacent to the first pad, the first electrode, and the multilayer semiconductor layer, a height of the insulating layer being lower than an upper surface of the multilayer semiconductor layer, and a second electrode on an upper surface of the multilayer semiconductor layer, an exposed lateral surface of the multilayer semiconductor layer, and a surface of the insulating layer, the second electrode connecting the second-type semiconductor layer and the second pad, an angle between the exposed lateral surface of the multilayer semiconductor layer and an upper surface of the insulating layer is 90 degrees or more.

### CROSS-REFERENCE TO RELATED APPLICATION

This application claims priority to Korean Patent Application No. 10-2023-0121382, filed on Sep. 12, 2023, in the Korean Intellectual Property Office, the disclosure of which is incorporated by reference herein in its entirety.

### BACKGROUND

### 1. Field

Embodiments of the present disclosure relate to a display apparatus and a method of manufacturing the display apparatus.

### 2. Description of Related Art

Liquid crystal displays (LCDs) and organic light-emitting diode (OLED) displays are widely used as display apparatuses. Recently, there has been an increasing interest in techniques for manufacturing high-resolution display apparatuses using micro-semiconductor chips (micro-light-emitting diodes). Light-emitting diodes (LEDs) are experiencing increased industrial demand owing to their characteristics such as low power consumption and environmental friendliness, and are applied not only to lighting devices and LCD backlights but also to display apparatuses.

In the production of display apparatuses using micro-semiconductor chips, a method of transferring micro-semiconductor chips onto a display board has been used. As the size of micro-semiconductor chips decreases and the size of display apparatuses increases, the productivity of display apparatuses decreases, and the difficulty of repair processes increases. Therefore, efforts have been made to find methods of improving the yield of manufacturing processes.

### SUMMARY

One or more example embodiments provide a display apparatus including micro-semiconductor chips shaped to improve the yield of manufacturing processes, and a method of manufacturing the display apparatus.

Additional aspects will be set forth in part in the description which follows and, in part, will be apparent from the description, or may be learned by practice of the presented embodiments of the disclosure.

According to an aspect of an example embodiment, there is provided a display apparatus including a display substrate, a first pad and a second pad on the display substrate spaced apart from each other, a first electrode on the first pad, a multilayer semiconductor layer including a first-type semiconductor layer, an active layer, and a second-type semiconductor layer that are sequentially on the first electrode in a first direction, an insulating layer on the display substrate and adjacent to the first pad, the first electrode, and the multilayer semiconductor layer, a height of an upper surface of the insulating layer being lower than an upper surface of the multilayer semiconductor layer, and a second electrode on an upper surface of the multilayer semiconductor layer, an exposed lateral surface of the multilayer semiconductor layer, and a surface of the insulating layer, the second electrode connecting the second-type semiconductor layer and the second pad to each other, wherein an angle between the exposed lateral surface of the multilayer semiconductor layer and an upper surface of the insulating layer is greater than or equal to 90 degrees.

The angle between the exposed lateral surface of the multilayer semiconductor layer and the upper surface of the insulating layer may be 90 degrees.

A width of the multilayer semiconductor layer in a second direction perpendicular to the first direction may be constant.

The angle between the exposed lateral surface of the multilayer semiconductor layer and the upper surface of the insulating layer may be greater than 90 degrees.

The multilayer semiconductor layer may include a first portion adjacent to the insulating layer and a second portion exposed from the insulating layer, and a width of the first portion of the multilayer semiconductor layer may be different from a width of the second portion of the multilayer semiconductor layer in a second direction perpendicular to the first direction varies.

An angle between a lateral surface of the insulating layer and an upper surface of the display substrate may be greater than or equal to 90 degrees.

The display apparatus may further include a driving device in the display substrate and electrically connected to the first electrode.

The display apparatus may further include a color conversion layer on the multilayer semiconductor layer, the color conversion layer being configured to convert a color of light emitted from the multilayer semiconductor layer.

According to another aspect of an example embodiment, there is provided a method of manufacturing a display apparatus, the method including forming a multilayer semiconductor layer on a first substrate, the multilayer semiconductor layer including a first-type semiconductor layer, an active layer, and a second-type semiconductor layer that are sequentially stacked in a first direction, forming a first electrode on the multilayer semiconductor layer, forming a micro-semiconductor chip by etching the multilayer semiconductor layer to correspond to the first electrode such that a width of the micro-semiconductor chip in a second direction perpendicular to the first direction is constant or decreases in the first direction away from the first electrode, transferring the micro-semiconductor chip onto a display substrate that comprises a first pad and a second pad such that the first electrode and the first pad contact each other, forming an insulating layer on the display substrate to a height such that the insulating layer is adjacent to the first pad, the first electrode, and the multilayer semiconductor layer an exposes an upper portion of the multilayer semiconductor layer, and forming a second electrode on an upper surface of the multilayer semiconductor layer, an exposed lateral surface of the multilayer semiconductor layer, and a surface of the insulating layer, the second electrode connecting the second-type semiconductor layer and the second pad to each other.

The forming of the micro-semiconductor chip may include a primary etching operation of the multilayer semiconductor layer such that a width of the multilayer semiconductor layer in a second direction perpendicular to the first direction increases in a direction away from the first electrode, and a secondary etching operation of the multilayer semiconductor layer such that the multilayer semiconductor layer has a constant width in the second direction perpendicular to the first direction.

The primary etching operation may include a dry etching method, and the secondary etching operation may include a wet etching method.

The forming of the micro-semiconductor chip may be performed by a dry etching method based on a hard mask layer such that a width of the multilayer semiconductor layer in a second direction perpendicular to the first direction is constant.

The forming of the micro-semiconductor chip may include primarily etching the multilayer semiconductor layer to a depth in the first direction at which the first substrate is not exposed, forming a material layer entirely on the multilayer semiconductor layer and the first electrode, placing a second substrate on the material layer and separating the first substrate from the multilayer semiconductor layer such that a surface of the multilayer semiconductor layer is separated from the first substrate and is exposed, secondarily etching the multilayer semiconductor layer from the surface of the multilayer semiconductor layer to expose the material layer, and removing the material layer

The secondary etching may be performed such that the multilayer semiconductor layer exposed above the material layer has a width in a second direction perpendicular to the first direction that decreases in the first direction away from the first electrode.

The forming of the insulating layer may include forming the insulation layer such that an angle between a lateral surface of the insulating layer and an upper surface of the display substrate is 90 degrees or more.

The transferring of the micro-semiconductor chip may include a fluid self-alignment transfer.

The transferring of the micro-semiconductor chip may include transferring the micro-semiconductor chip to a transfer substrate including a plurality of grooves.

The plurality of grooves may form a plurality of groups, each of the plurality of groups including one or more adjacent grooves, and the plurality of groups being regularly arranged.

The forming of the insulating layer may include forming the insulating layer entirely on the first pad, the first electrode, and the multilayer semiconductor layer, and polishing an upper portion of the insulating layer to expose the upper portion of the multilayer semiconductor layer.

The polishing of the upper portion of the insulating layer may include removing a portion of the second-type semiconductor layer of the multilayer semiconductor layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view schematically illustrating a configuration of a display apparatus according to an example embodiment;

FIG. 2 is a cross-sectional view schematically illustrating a configuration of a display apparatus according to a related example;

FIG. 3 is a cross-sectional view schematically illustrating a configuration of a display apparatus according to another example embodiment;

FIG. 4 is a cross-sectional view schematically illustrating a configuration of a display apparatus according to another example embodiment;

FIG. 5 is a cross-sectional view schematically illustrating a configuration of a display apparatus according to another example embodiment;

FIGS. 6A, 6B, 6C, 6D, 6E, 6F, 6G, 6H, 6I, and 6J are view illustrating a method of manufacturing a display apparatus according to an example embodiment;

FIGS. 7A and 7B are view illustrating a method of manufacturing a display apparatus according to an example embodiment;

FIG. 8 is a view illustrating a micro-semiconductor chip transfer process in a display apparatus manufacturing method according to an example embodiment;

FIGS. 9, 10, 11, and 12 are views illustrating examples in which micro-semiconductor chips are transferred to transfer substrates used in a display apparatus manufacturing method, according to example embodiments;

FIGS. 13A, 13B, 13C, 13D, 13E, 13F, 13G, 13H, and 13I are view illustrating a method of manufacturing a display apparatus according to another example embodiment;

FIG. 14 is a block diagram illustrating an electronic device according to an example embodiment; and

FIGS. 15, 16, 17, 18, and 19 are views illustrating various electronic devices to which display apparatuses are applied according to example embodiments.

### DETAILED DESCRIPTION

Reference will now be made in detail to embodiments, examples of which are illustrated in the accompanying drawings, wherein like reference numerals refer to like elements throughout. In this regard, the example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. For example, the expression, “at least one of a, b, and c,” should be understood as including only a, only b, only c, both a and b, both a and c, both b and c, or all of a, b, and c.

Hereinafter, example embodiments will be described with reference to the accompanying drawings. The example embodiments described herein are for illustrative purposes only, and various modifications may be made therein. In the drawings, like reference numerals refer to like elements, and the sizes of elements may be exaggerated for clarity of illustration.

In the following description, when an element is referred to as being “above” or “on” another element, it may be directly on the other element while making contact with the other element or may be above the other element without making contact with the other element.

Although the terms “first” and “second” are used to describe various elements, these terms are only used to distinguish one element from another element. These terms do not limit elements to having different materials or structures.

The terms of a singular form may include plural forms unless otherwise mentioned. It will be further understood that the terms “comprises” and/or “comprising” used herein specify the presence of stated features or elements, but do not preclude the presence or addition of one or more other features or elements.

In the disclosure, terms such as “unit” or “module” may be used to denote a unit that has at least one function or operation and is implemented with hardware, software, or a combination of hardware and software.

An element referred to with the definite article or a demonstrative determiner may be construed as the element or the elements even though it has a singular form.

Operations of a method may be performed in appropriate order unless explicitly described in terms of order or described to the contrary. In addition, examples or exemplary terms (for example, “such as” and “etc.”) are used for the purpose of description and are not intended to limit the scope of the inventive concept unless defined by the claims.

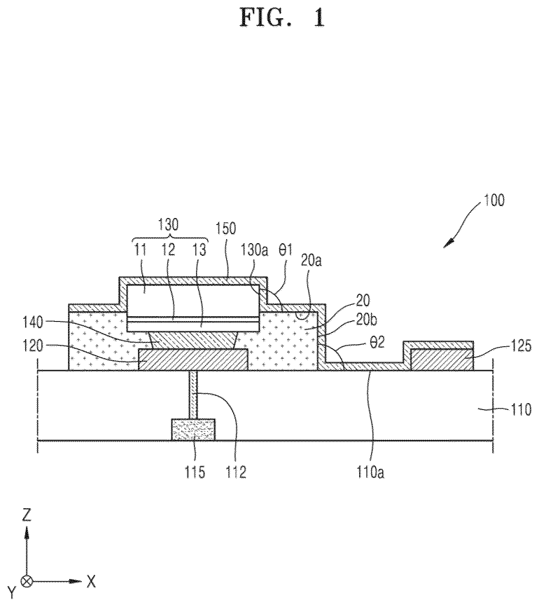

FIG. 1 is a cross-sectional view schematically illustrating a configuration of a display apparatus 100 according to an example embodiment.

The display apparatus 100 includes a display substrate 110, a first pad 120 and a second pad 125 that are spaced apart from each other on the display substrate 110 in a second direction (X direction), a first electrode 140 disposed on the first pad 120, a multilayer semiconductor layer 130 disposed on the first electrode 140, and a second electrode 150 disposed on an upper surface of the multilayer semiconductor layer 130.

The first electrode 140 and the multilayer semiconductor layer 130 formed on the first electrode 140 may be manufactured separately based on a substrate other than the display substrate 110 and may be transferred onto the display substrate 110. A structure in which the multilayer semiconductor layer 130 is formed on the first electrode 140 may hereinafter be referred to as a micro-semiconductor chip. Although FIG. 1 illustrates one micro-semiconductor chip for ease of illustration, a plurality of micro-semiconductor chips may be disposed on the display substrate 110.

The micro-semiconductor chips may include various types of semiconductor chips having a micro-size. The micro-size may be about 1,000 μm or less or about 200 μm or less. For example, the micro-semiconductor chips may include a light emitting diode (LED), a complementary metal-oxide semiconductor (CMOS), a CMOS image sensor (CIS), a vertical-cavity surface-emitting laser (VCSEL), a photodiode (PD), a memory device, a two-dimensional (2D) material device, or the like. The 2D material may be graphene, carbon nanotubes (CNT), or the like.

The multilayer semiconductor layer 130 includes a first-type semiconductor layer 13, an active layer 12, and a second-type semiconductor layer 11 that are sequentially stacked in a first direction (Z direction).

The first-type semiconductor layer 13 may be a p-type semiconductor layer. The first-type semiconductor layer 13 may include a p-type Group III-V semiconductor such as p-GaN. The first-type semiconductor layer 13 may have a single-layer or multi-layer structure.

The active layer 12 may be provided on an upper surface of the first-type semiconductor layer 13. Light may be generated when electrons and holes combine with each other in the active layer 12. The active layer 12 may have a multi-quantum well (MQW) structure or a single-quantum well (SQW) structure. The active layer 12 may include a Group III-V semiconductor such as gallium nitride (GaN).

The second-type semiconductor layer 11 may be provided on an upper surface of the active layer 12. The second-type semiconductor layer 11 may be, for example, an n-type semiconductor layer. The second-type semiconductor layer 11 may include an n-type Group III-V semiconductor such as n-GaN. The second-type semiconductor layer 11 may have a single-layer or multi-layer structure. According to another example embodiment, when the first-type semiconductor layer 13 is an n-type semiconductor layer, the second-type semiconductor layer 11 may be a p-type semiconductor layer.

The display substrate 110 may include at least a portion of a circuit element configured to drive the micro-semiconductor chip. The display substrate 110 may include a driving element 115 configured to drive the micro-semiconductor chip. The driving element 115 may include at least one capacitor and at least one transistor. The driving element 115 may be connected to the first pad 120 through a wire 112 and may be electrically connected to the micro-semiconductor chip.

The second electrode 150 extends from the upper surface of the multilayer semiconductor layer 130 and is connected to the second pad 125. An insulating layer 20 may be formed in a path along which the second electrode 150 extends to the second pad 125. For example, the second electrode 150 is formed from the upper surface of the multilayer semiconductor layer 130 to an upper surface of the second pad 125 along a lateral surface 130a of the multilayer semiconductor layer 130, an upper surface 20a of the insulating layer 20, and a lateral surface 20b of the insulating layer 20. FIG. 1 illustrates that the second pad 125 is spaced apart from the insulating layer 20, and the second electrode 150 extends to the second pad 125 along an upper surface 110a of the display substrate 110. However, this is merely an example, and the second pad 125 may be in contact with the insulating layer 20.

The insulating layer 20 may include, for example, a photoresist material, but is not limited thereto.

The insulating layer 20 is provided adjacent to and surrounds the first pad 120 and the first electrode 140. In addition, the insulating layer 20 is provided adjacent to and surrounds a portion of the multilayer semiconductor layer 130. The height of the insulating layer 20 compared to the upper surface 110a of the display substrate 110 is such that an upper portion of the multilayer semiconductor layer 130 may be exposed and an upper surface of the insulating layer 20 may be lower than an upper surface of the multilayer semiconductor layer 130 in a first direction (Z direction). For example, as shown in FIG. 1, a portion of the second-type semiconductor layer 11, the active layer 12, and the first-type semiconductor layer 13 may be surrounded by the insulating layer 20.

The lateral surface 130a of the multilayer semiconductor layer 130 exposed above the insulating layer 20 may be at an angle θ1 of about 90 degrees or more with respect to the upper surface 20a of the insulating layer 20. The angle θ1, that is, the angle formed counterclockwise from the upper surface 20a of the insulating layer 20 to the lateral surface 130a of the multilayer semiconductor layer 130 as shown in FIG. 1, may be about 90 degrees or more. FIG. 1 illustrates that the angle θ1 is about 90 degrees. Thus, the width of the exposed portion of the multilayer semiconductor layer 130, that is, the width of the exposed portion of the multilayer semiconductor layer 130 in a second direction (X direction) perpendicular to the first direction (Z direction) which is the stacking direction, may be constant in the first direction.

An angle θ2 formed counterclockwise from the upper surface 110a of the display substrate 110 to the lateral surface 20b of the insulating layer 20 as shown in FIG. 1 may also be about 90 degrees or more. FIG. 1 illustrates that the angle θ2 is about 90 degrees.

A vertical electrode structure in which the first electrode 140 and the second electrode 150 are vertically arranged with the multilayer semiconductor layer 130 therebetween may cause manufacturing process errors because the second electrode 150 and the second pad 125 are connected to each other while overcoming a stepped structure.

In the display apparatus 100 of the example embodiment, the slope of the lateral surface 130a of the multilayer semiconductor layer 130 is determined to reduce such errors.

For example, when the angle θ2 from the upper surface 20a of the insulating layer 20 to the lateral surface 130a of the multilayer semiconductor layer 130 is less than about 90 degrees, a short circuit may occur at the second electrode 150.

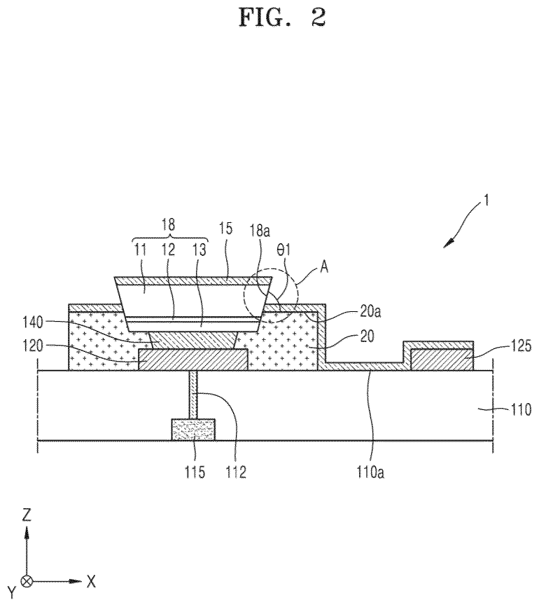

FIG. 2 is a cross-sectional view schematically illustrating a configuration of a display apparatus 1 according to a related example.

In the display apparatus 1 of the related example, an angle θ1 between a lateral surface 18a of a multilayer semiconductor layer 18 and an upper surface 20a of an insulating layer 20 is less than about 90 degrees.

In a general vertical chip manufacturing process, the multilayer semiconductor layer 18 disposed on a first electrode 140 has an inverted trapezoidal cross-sectional shape. After the multilayer semiconductor layer 18 is surrounded by the insulating layer 20, when a polishing operation such as chemical mechanical polishing (CMP) is performed to expose the multilayer semiconductor layer 18, the insulating layer 20 may be etched more than the multilayer semiconductor layer 18 because of a CMP selectivity difference or a hardness difference between a material included in the multilayer semiconductor layer 18 and a material included in the insulating layer 20. In this case, the lateral surface 18a of the multilayer semiconductor layer 18 may be exposed above the insulating layer 20.

When the lateral surface 18a of the multilayer semiconductor layer 18 exposed as described above is at an angle of less than about 90 degrees with respect to the upper surface 20a of the insulating layer 20, a material of a second electrode 15 may not be properly deposited on the lateral surface 18a angled as described above, and a short circuit may occur at the second electrode 15 as indicated in a portion A of FIG. 2.

It is difficult to repair such defects, and thus, the display apparatus 100 of the example embodiment is provided to realize a process in which electrode connection is made with a low defect rate.

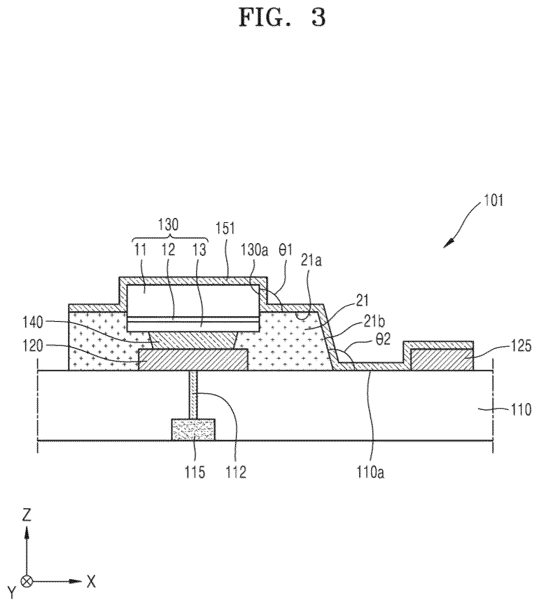

FIG. 3 is a cross-sectional view schematically illustrating a configuration of a display apparatus 101 according to another example embodiment.

The display apparatus 101 of the example embodiment is different from the display apparatus 100 shown in FIG. 1 in that an angle θ2 from an upper surface 110a of a display substrate 110 to a lateral surface 21b of an insulating layer 21 is greater than about 90 degrees. An angle θ1 between an upper surface 21a of the insulating layer 21 and a lateral surface 130a of a multilayer semiconductor layer 130 may be about 90 degrees or more as in the example embodiment shown in FIG. 1.

The angle θ2 may be greater than about 90 degrees depending on an etching method used for patterning the insulating layer 21, and in this case, a defect rate indicating the possibility of a short circuit at a second electrode 151 may be lower than in the case in which the angle θ2 is about 90 degrees.

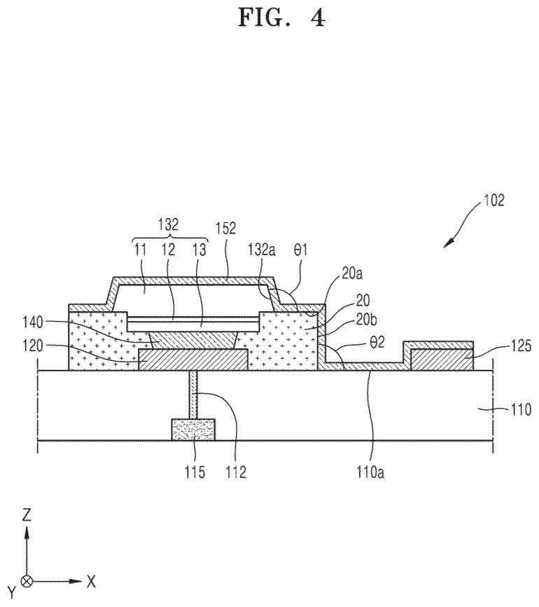

FIG. 4 is a cross-sectional view schematically illustrating a configuration of a display apparatus 102 according to another example embodiment.

The display apparatus 102 of the example embodiment is different from the display apparatus 100 shown in FIG. 1 in the shape of a multilayer semiconductor layer 132 and the shape of a second electrode 152 that is affected by the shape of the multilayer semiconductor layer 132.

A lateral surface 132a of the multilayer semiconductor layer 132 exposed above an insulating layer 20 is at an angle θ1 of greater than about 90 degrees with respect to an upper surface 20a of an insulating layer 20.

In the multilayer semiconductor layer 132, the horizontal width (X-direction width) of a portion surrounded by the insulating layer 20 is different from the horizontal width (X-direction width) of a portion exposed above the insulating layer 20. The portion of the multilayer semiconductor layer 132 surrounded by the insulating layer 20 may have a width in a second direction (X direction) perpendicular to a first direction (Z direction), and the width may be constant in the first direction. The portion of the multilayer semiconductor layer 132 protruding above the insulating layer 20 may have a width in the second direction (X direction) perpendicular to the first direction (Z direction) that decreases in the first direction (Z direction), that is, in a direction away from a first electrode 140.

The multilayer semiconductor layer 132 may be shaped as described above through a manufacturing process in which the lateral surface 132a of the multilayer semiconductor layer 132 is inclined at the angle θ1. A manufacturing method for this will be described later.

Although FIG. 4 illustrates that an angle θ2 between the insulating layer 20 and an upper surface 110a of a display substrate 110 is about 90 degrees, embodiments are not limited thereto. For example, the angle θ2 may be greater than about 90 degrees as in the embodiment shown in FIG. 3.

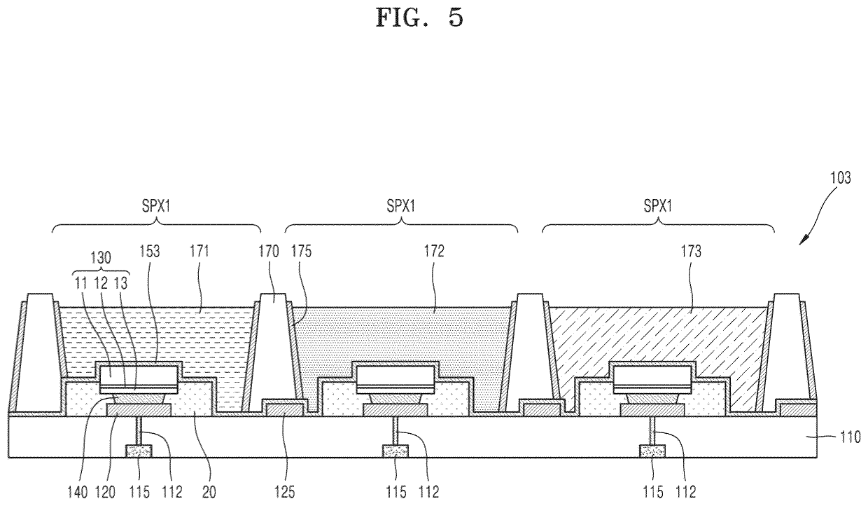

FIG. 5 is a cross-sectional view schematically illustrating a configuration of a display apparatus 103 according to another example embodiment.

The display apparatus 103 may include a first subpixel SPX1, a second subpixel SPX2, and a third subpixel SPX3 that form one pixel. The display apparatus 103 may include a plurality of pixels.

As in the example embodiment shown in FIG. 1, the first subpixel SPX1, the second subpixel SPX2, and the third subpixel SPX3 may each include a first pad 120, a first electrode 140, a multilayer semiconductor layer 130, a second electrode 153, and a second pad 125.

The second electrode 153 may be a common electrode through which second-type semiconductor layers 11 of the multilayer semiconductor layers 130 respectively provided in the first subpixel SPX1, the second subpixel SPX2, and the third subpixel SPX3 are connected to the second pads 125 respectively provided in the first subpixel SPX1, the second subpixel SPX2, and the third subpixel SPX3.

The shapes of the multilayer semiconductor layers 130 and the shape of the second electrode 153 are illustrated as being similar to those of the display apparatus 100 shown in FIG. 1, but may be similar to those of the display apparatus 101 shown in FIG. 3 or those of the display apparatus 102 shown in FIG. 4.

Barrier walls 170 may be provided between the first subpixel SPX1, the second subpixel SPX2, and the third subpixel SPX3. Reflective layers 175 may be further provided on the barrier walls 170.

In the first subpixel SPX1, the second subpixel SPX2, and the third subpixel SPX3, color conversion layers may be provided to cover the multilayer semiconductor layers 130. The color conversion layers may include a first color conversion layer 171 configured to convert light generated by a corresponding multilayer semiconductor layer 130 into first-color light, a second color conversion layer 172 configured to convert light generated by a corresponding multilayer semiconductor layer 130 into second-color light, and a third color conversion layer 173 configured to convert light generated by a corresponding multilayer semiconductor layer 130 into third-color light.

The multilayer semiconductor layers 130 may emit first-color light, for example, blue light. However, this is merely an example, and the multilayer semiconductor layers 130 may emit light having other wavelengths capable of exciting the color conversion layers. Second-color light may be, for example, green light, and third-color light may be, for example, red light.

When the multilayer semiconductor layers 130 emit blue light, the first color conversion layer 171 may include a resin that transmits blue light without converting the blue light. The second color conversion layer 172 may emit green light by converting blue light emitted from the multilayer semiconductor layer 130. The second color conversion layer 172 may include quantum dots (QDs) that are excited by blue light and emit green light. The QDs may have a core-shell structure formed by a core portion and a shell portion, or may have a particle structure not provided with a shell. The core-shell structure may be a single-shell structure or a multi-shell structure such as a double-shell structure.

The QDs may include a Group II-VI semiconductor, a Group III-V semiconductor, a Group IV-VI semiconductor, a Group IV semiconductors, and/or graphene QDs. The QDs may include, for example, cadmium (Cd), selenium (Se), zinc (Zn), sulfur (S), and/or indium phosphide (In)P, and each of the QDs may have a diameter of several tens of nanometers (nm) or less, or a diameter of about 10 nm or less. The second color conversion layer 172 may include a phosphor that is capable of emitting green light when excited by blue light emitted from the multilayer semiconductor layer 130.

The third color conversion layer 173 may emit red light by converting blue light emitted from the multilayer semiconductor layer 130. The third color conversion layer 173 may include QDs having a predetermined size and capable of emitting red light when excited by blue light, or may include a phosphor that is capable of emitting red light when excited by blue light emitted by the multilayer semiconductor layer 130. Color images may be displayed through the first color conversion layer 171, the second color conversion layer 172, and the third color conversion layer 173.

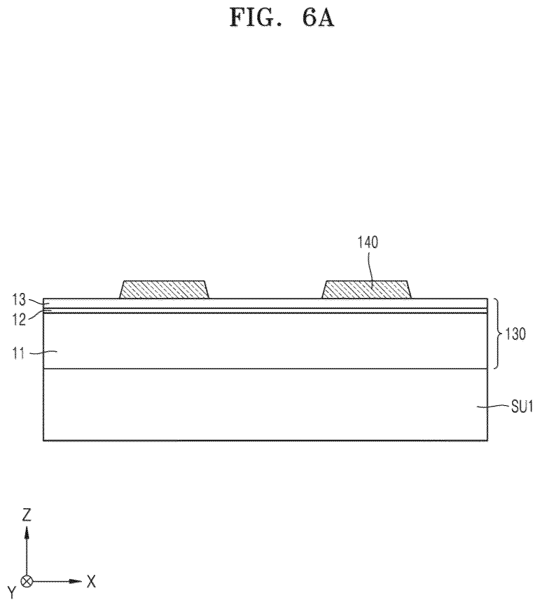

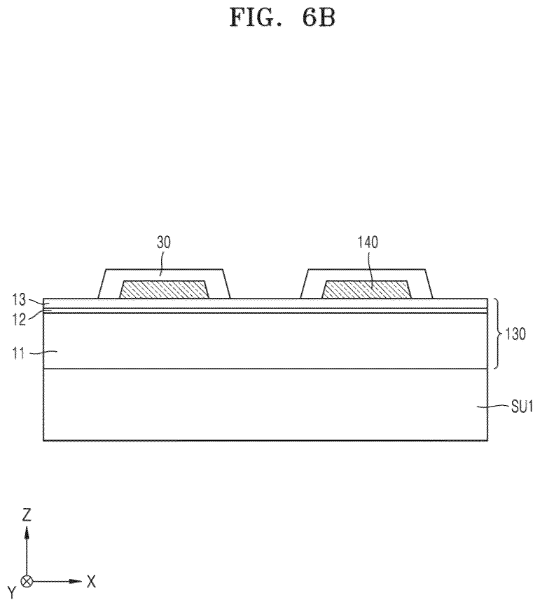

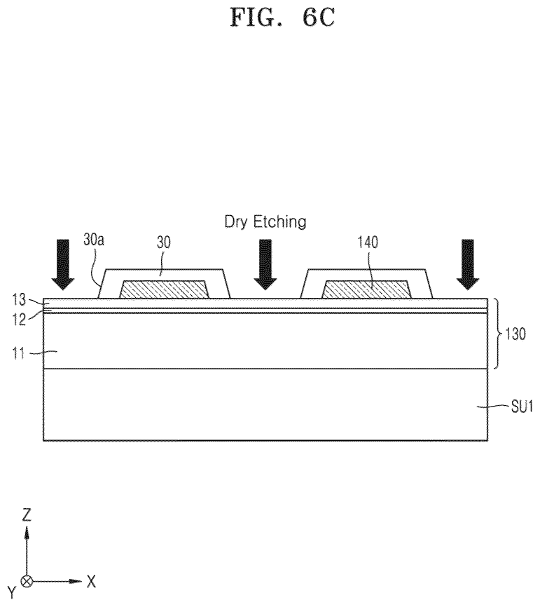

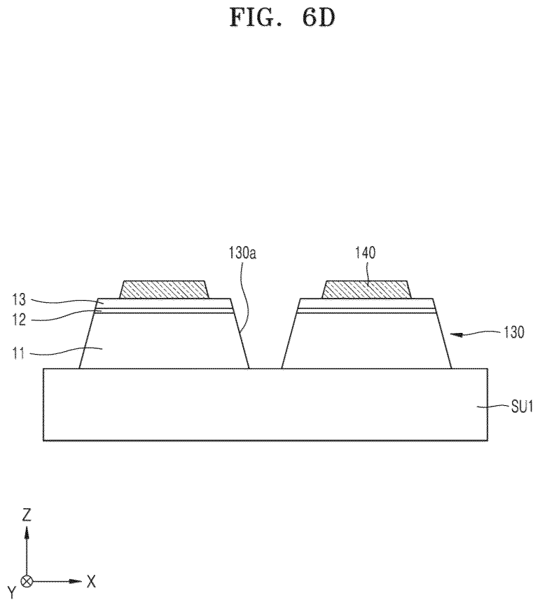

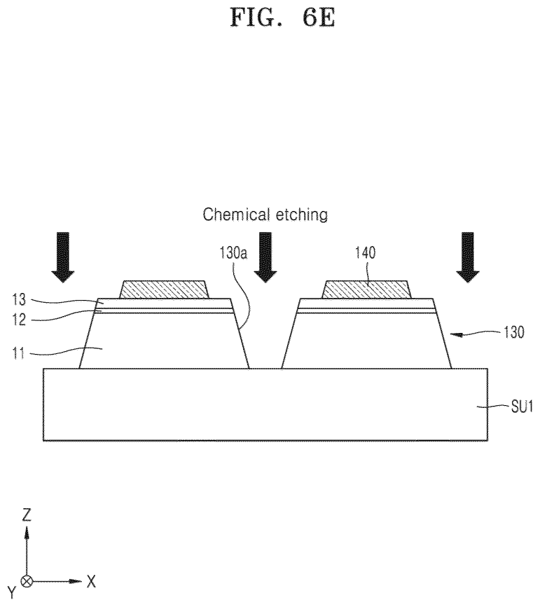

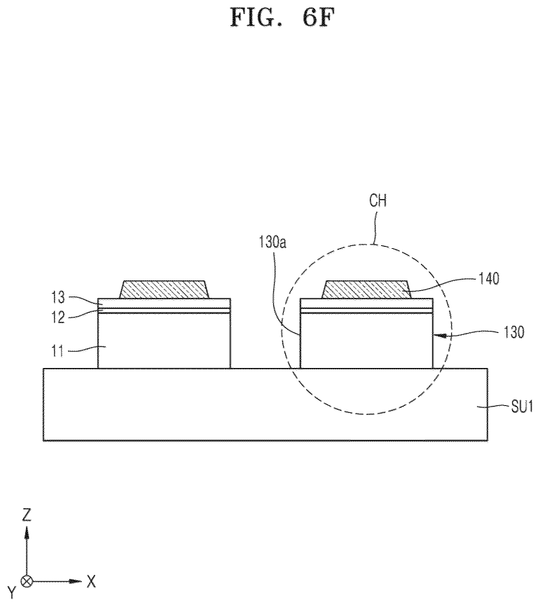

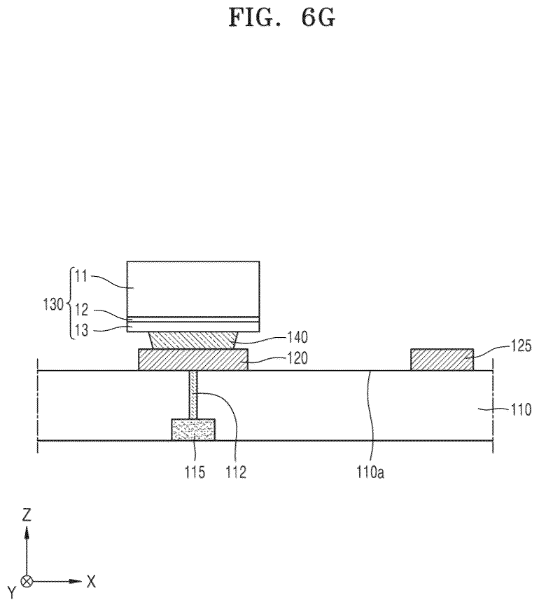

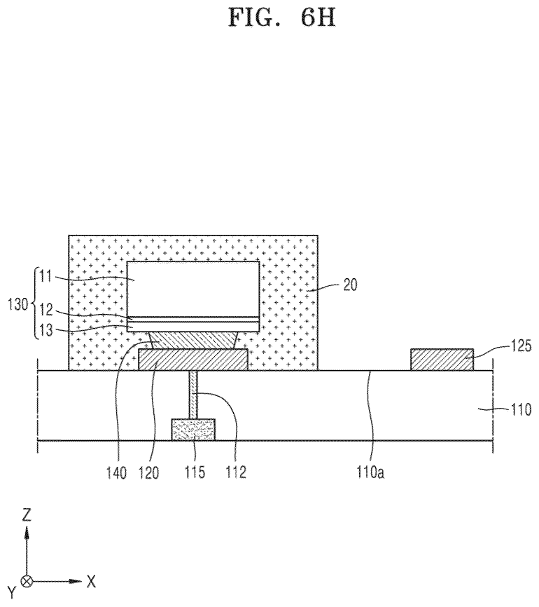

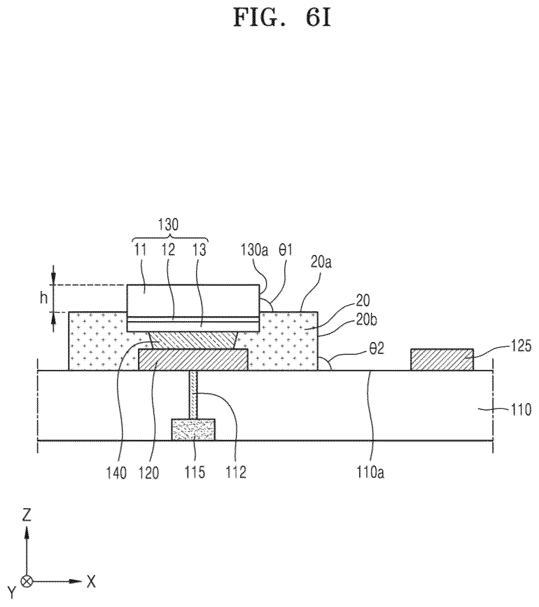

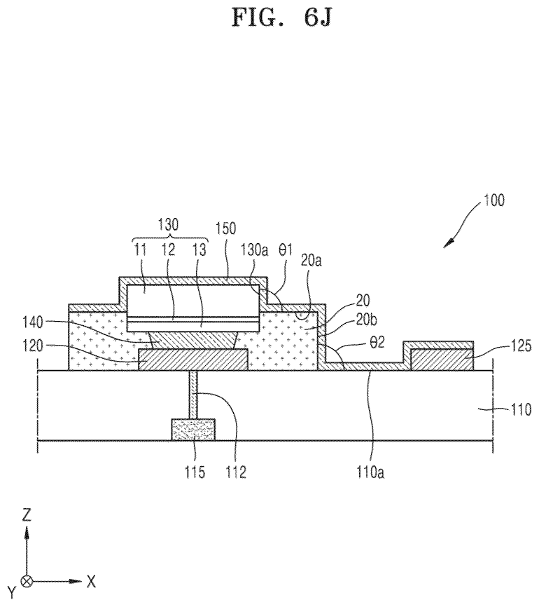

FIGS. 6A to 6J are view illustrating a method of manufacturing a display apparatus according to an embodiment.

Referring to FIG. 6A, a multilayer semiconductor layer 130 is formed on a first substrate SU1, and a first electrode 140 is formed on the multilayer semiconductor layer 130.

The multilayer semiconductor layer 130 includes a second-type semiconductor layer 11, an active layer 12, and a first-type semiconductor layer 13 that are stacked in a first direction (Z direction).

After a layer including a material that is to be used as first electrodes 140 is formed on the first-type semiconductor layer 13, the layer is patterned to form a plurality of first electrodes 130.

Referring to FIG. 6B, a photoresist layer 30 is formed on the first electrodes 140. The photoresist layer 30 is used as a mask for patterning the multilayer semiconductor layer 130 into a shape corresponding to the first electrodes 140.

Referring to FIG. 6C, in a primary etching operation, the multilayer semiconductor layer 130 is etched using the photoresist layer 30 as a mask. For example, a dry etching method may be used in the primary etching operation. In the primary etching operation, an etched lateral surface shape of the multilayer semiconductor layer 130 may be affected by the angle of a lateral surface 30a of the photoresist layer 30.

Referring to FIG. 6D, a lateral surface 130a of the multilayer semiconductor layer 130 that is etched has an inclination angle similar to the inclination angle of the lateral surface 30a of the photoresist layer 30 shown in FIG. 6C.

When structures in which the first electrodes 140 are formed on the multilayer semiconductor layer 130 having the shape described above are transferred to a display substrate and used, electrode defects may occur as described with reference to FIG. 2.

Referring to FIG. 6E, a secondary etching operation is performed on the multilayer semiconductor layer 130.

The secondary etching operation is an additional etching operation for changing the slope of the lateral surface 130a of the multilayer semiconductor layer 130, and, for example, a chemical etching method that is a wet etching method may be used in the secondary etching operation. In the secondary etching operation, a wet etchant may be used depending on the crystal direction of a material included in the multilayer semiconductor layer 130.

Referring to FIG. 6F, the lateral surface 130a of the multilayer semiconductor layer 130 has an angle of about 90 degrees. The multilayer semiconductor layer 130 having the shape described above and a first electrodes 140 formed on the multilayer semiconductor layer 130 may be referred to as a micro-semiconductor chip CH. The micro-semiconductor chips CH is separated from the first substrate SU1 and transferred onto a display substrate 110 as shown in FIG. 6G.

The micro-semiconductor chip CH manufactured as shown in FIG. 6F may be transferred onto the display substrate 110 as shown in FIG. 6G by, for example, a dry transfer method such as a pick-and-place method or a wet transfer method using a liquid like a fluid self-alignment method.

The display substrate 110 include a first pad 120 and a second pad 125, and the first electrode 140 is bonded to the first pad 120.

Referring to FIG. 6H, an insulating layer 20 is formed to cover the first pad 120, the first electrode 140, and the multilayer semiconductor layer 130. The insulating layer 20 may include, for example, a photoresist material.

Referring to FIG. 6I, a CMP operation is performed to expose a portion of the multilayer semiconductor layer 130. In this case, due to the difference in CMP selectivity or hardness between the material of the multilayer semiconductor layer 130 and the material of the insulating layer 20, the material of the insulating layer 20 is polished more than the material of the multilayer semiconductor layer 130 such that the multilayer semiconductor layer 130 may be partially exposed above the insulating layer 20. However, embodiments are not limited thereto. A height (h) to which the multilayer semiconductor layer 130 protrudes above the insulating layer 20 may vary depending on CMP conditions and the hardness difference between the material of the insulating layer 20 and the material of the multilayer semiconductor layer 130. The height (h) is greater than 0 and is not particularly limited. In the CMP operation, the material of the second-type semiconductor layer 11 included in the multilayer semiconductor layer 130 is also partially polished and removed. The second-type semiconductor layer 11 may include a plurality of layers having different doping concentrations, and a portion of the second-type semiconductor layer 11 removed in the CMP operation may have a low doping concentration. The lateral surface 130a of the multilayer semiconductor layer 130 that is exposed may be at an angle θ1 of about 90 degrees with respect to an upper surface 20a of the insulating layer 20. Although FIG. 6I illustrates that an angle θ2 between the insulating layer 20 and an upper surface 110a of the display substrate 110 is about 90 degrees, embodiments are not limited thereto, and the angle θ2 may be greater than about 90 degrees.

Referring to FIG. 6J, a display apparatus 100 is provided in which a second electrode 150 extends from an upper surface of the multilayer semiconductor layer 130 to the second pad 125. The second electrode 150 is in contact with the second-type semiconductor layer 11. In the CMP operation described with reference to FIG. 6I, a region of the second-type semiconductor layer 11 having a relatively low doping concentration may be removed, and thus, the second electrode 150 may be in contact with the second-type semiconductor layer 11 in a region having a relatively high doping concentration or a region close to the region having a relatively high doping concentration.

A material of the second electrode 150 may be formed on the lateral surface 130a of the multilayer semiconductor layer 130, and therefore, a defect rate indicating the possibility of a short circuit at the second electrode 150 may decrease.

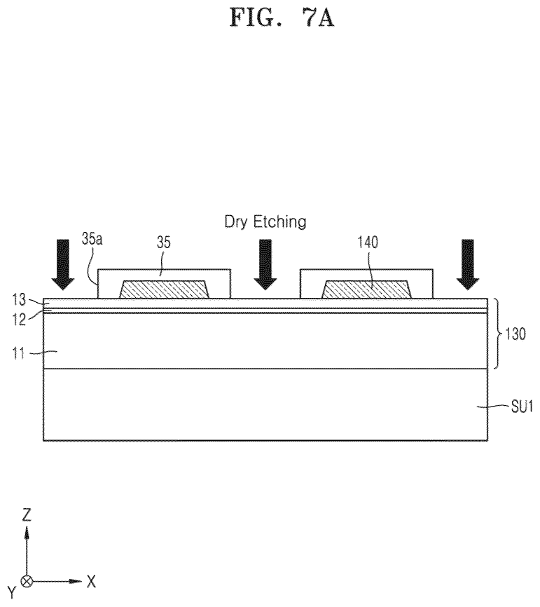

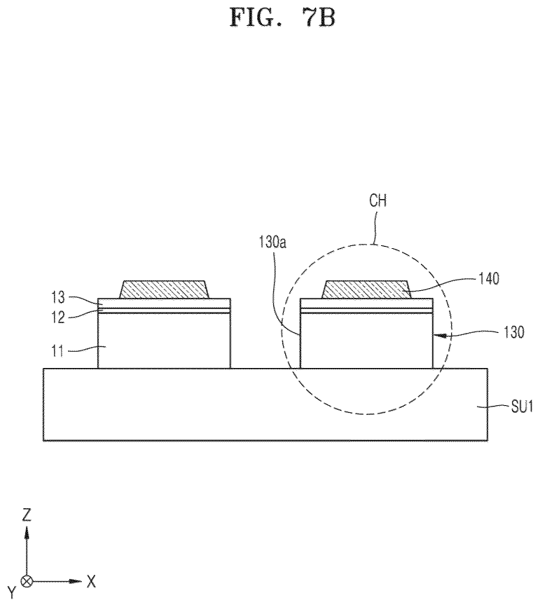

FIGS. 7A and 7B are view illustrating a method of manufacturing a display apparatus according to an example embodiment.

The manufacturing method of the example embodiment is similar to operations of the manufacturing method described with reference to FIGS. 6B to 6F, and thus, only the modified operations will now be described.

Referring to FIG. 7A, a hard mask layer 35 is formed to cover a first electrode 140 formed on a multilayer semiconductor layer 130. A metallic material may be used to form the hard mask layer 35. As illustrated in FIG. 7A, the hard mask layer 35 may have a lateral surface 35a formed at an angle of about 90 degrees unlike the photoresist layer 30 used as a mask in FIG. 6B. Therefore, an etched lateral surface of the multilayer semiconductor layer 130 formed through an etching operation using the hard mask layer 35 may have an angle similar to the angle of the lateral surface 35a of the hard mask layer 35. After the etching operation is completed, the hard mask layer 35 is removed.

Referring to FIG. 7B, the angle of the lateral surface 130a of the multilayer semiconductor layer 130 may be about 90 degrees similar to the example embodiment shown in FIG. 6F, in which a two-stage etching operation including primary dry etching and secondary wet etching is performed.

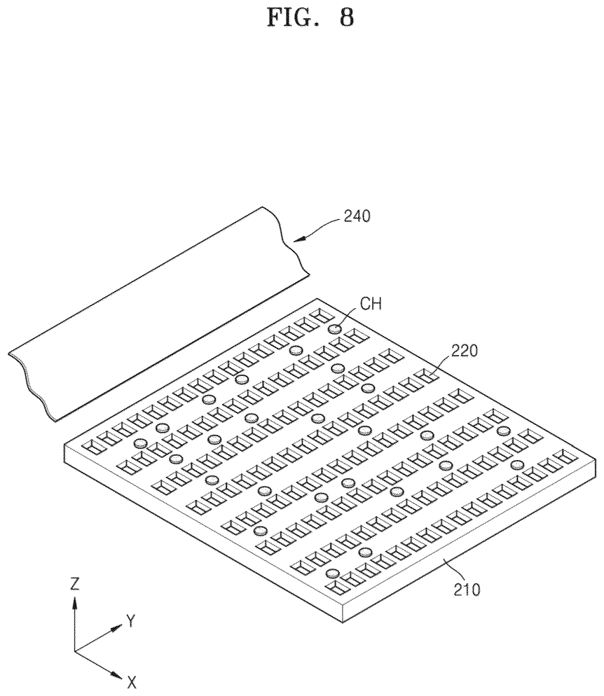

FIG. 8 is a view illustrating an operation in which micro-semiconductor chips CH are transferred by a wet transfer method when a display apparatus manufacturing method is performed according to an example embodiment.

For example, when micro-semiconductor chips CH manufactured as shown in FIG. 6F are transferred onto the display substrate 110 as shown in FIG. 6G, the wet transfer method may be used.

A transfer substrate 210 including a plurality of grooves 220 is prepared. The transfer substrate 210 may have a single layer or a plurality of layers. The transfer substrate 210 may include grooves 220 to accommodate micro-semiconductor chips CH. A liquid is supplied to the grooves 220. Any type of liquid may be used as long as the liquid does not corrode or damage micro-semiconductor chips CH. For example, the liquid may include one or a combination selected from the group including water, ethanol, alcohol, polyol, ketone, halocarbon, acetone, flux, and an organic solvent. The organic solvent may include, for example, isopropyl alcohol (IPA). The liquid is not limited thereto and may be variously modified.

Various methods such as a spray method, a dispensing method, an inkjet dot method, or a method of flowing the liquid onto the transfer substrate 210 may be used to supply the liquid to the grooves 220. In addition, the amount of the liquid may be variously adjusted such that the grooves 220 may be exactly filled with the liquid or overflow with the liquid.

A plurality of micro-semiconductor chips CH are supplied to the transfer substrate 210. The micro-semiconductor chips CH may be directly sprinkled on the transfer substrate 210 without using any other liquid, or may be supplied in a state in which the micro-semiconductor chips CH are contained in a suspension. Various methods, such as a spray method, a dispensing method in which liquid is dropped in droplets, an inkjet dot method in which liquid is ejected like a printing method, or a method in which the suspension is allowed to flow onto the transfer substrate 210, may be used to supply the micro-semiconductor chips CH contained in the suspension.

The micro-semiconductor chips CH may be transferred to the grooves 220 by scanning the transfer substrate 210 with a wiper 240. The micro-semiconductor chips CH may be transferred such that first electrodes 140 (refer to FIG. 6F) may face upper sides of the grooves 220. The micro-semiconductor chips CH arranged in the grooves 220 of the transfer substrate 210 are transferred to the display substrate 110 (refer to FIG. 6G) to bond the first electrodes 140 (refer to FIG. 6F) to the first pads 120 of the display substrate 110.

In the operation of transferring the micro-semiconductor chips CH to the transfer substrate 210, in order to facilitate the operations of sub-pixels and minimize repair processes, a redundancy process may be used in which a plurality of micro-semiconductor chips CH are transferred and arranged in each pixel.

Although FIG. 8 illustrates that the grooves 220 of the transfer substrate 210 are regularly arranged as a whole, groups each including a plurality of adjacent grooves 220 may be regularly arranged.

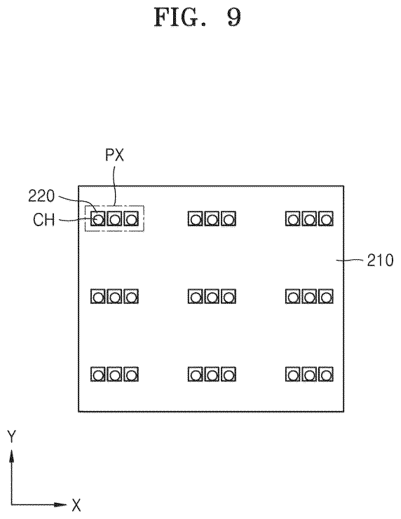

FIGS. 9 to 12 illustrate examples of a redundancy array structure, in which a plurality of micro-semiconductor chips are transferred to each pixel of a transfer substrate used in a method of manufacturing a display apparatus, according to example embodiments.

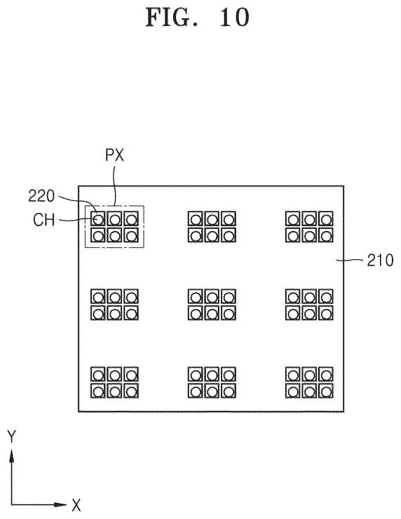

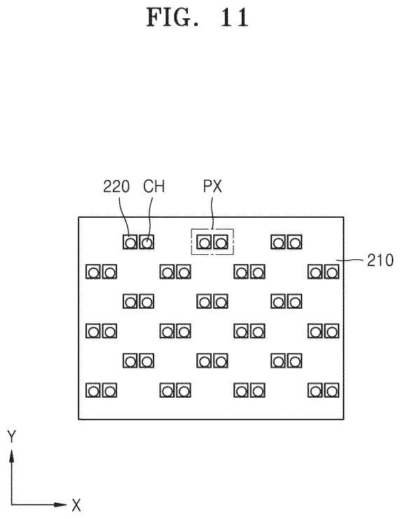

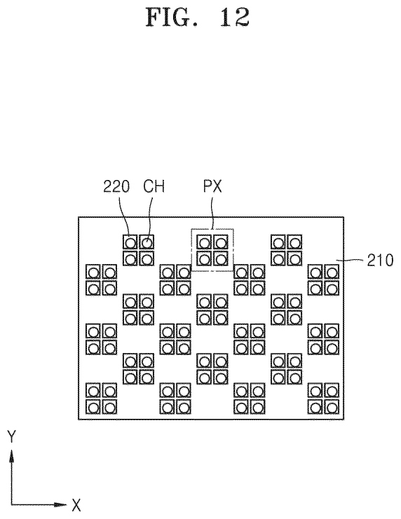

FIG. 9 illustrates an example in which three micro-semiconductor chips CH are transferred in a row to each pixel PX of a transfer substrate 210. FIG. 10 illustrates an example in which micro-semiconductor chips CH are transferred in a 2×3 redundancy array structure to each pixel PX. FIG. 11 illustrates an example in which two micro-semiconductor chips CH are transferred to each pixel PX. FIG. 12 illustrates an example in which four micro-semiconductor chips CH are transferred to each pixel PX. FIGS. 9 and 10 illustrate strip-pattern redundancy array structures, and FIGS. 11 and 12 illustrate pantile redundancy array structures. In embodiments, any redundancy array transfer structures may be applied to display apparatuses.

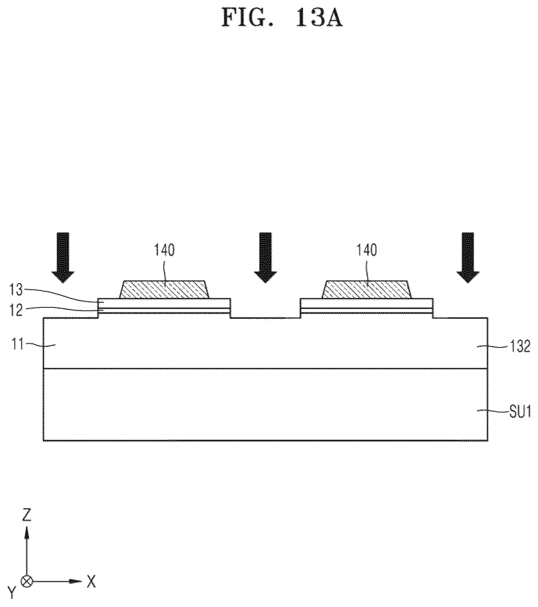

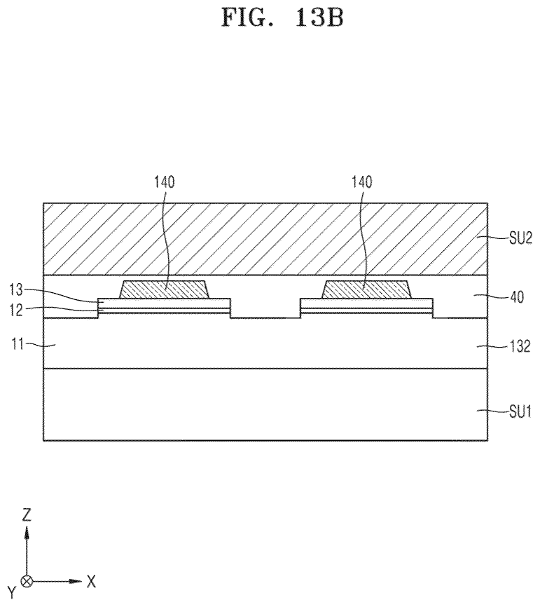

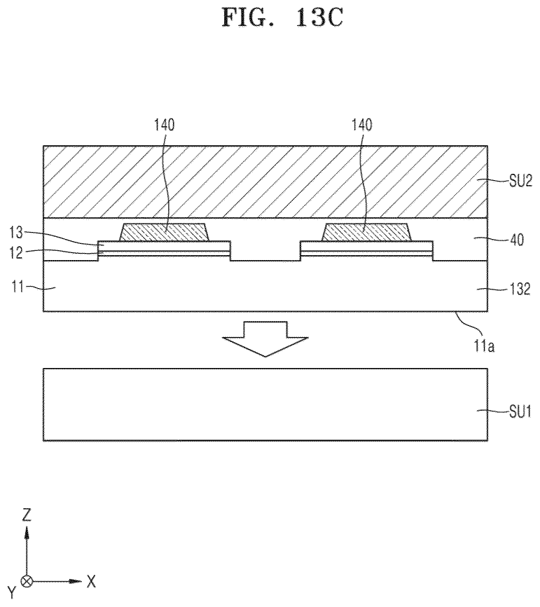

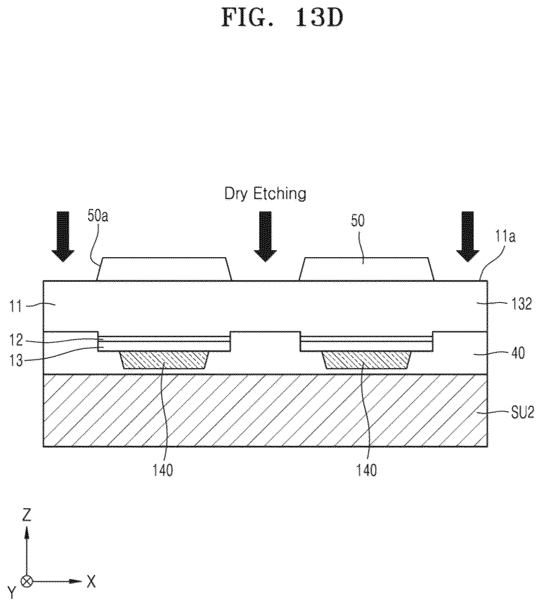

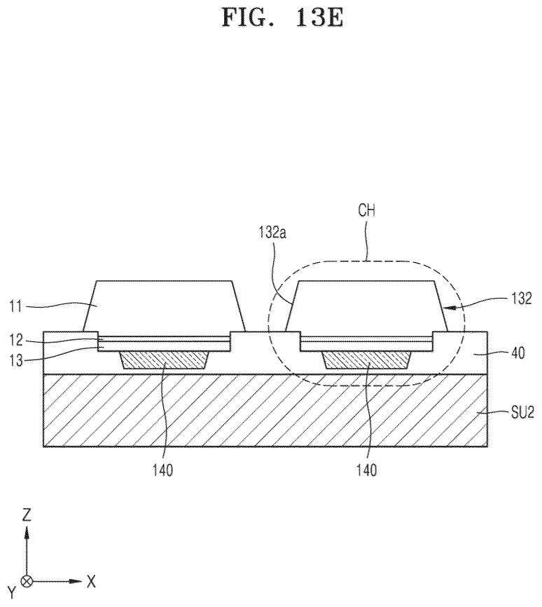

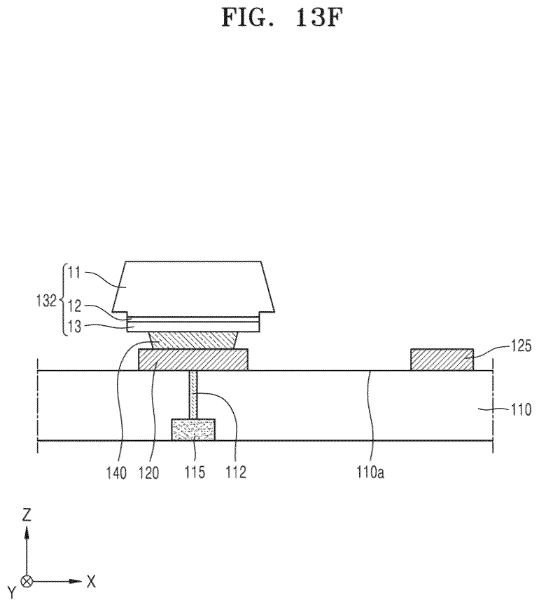

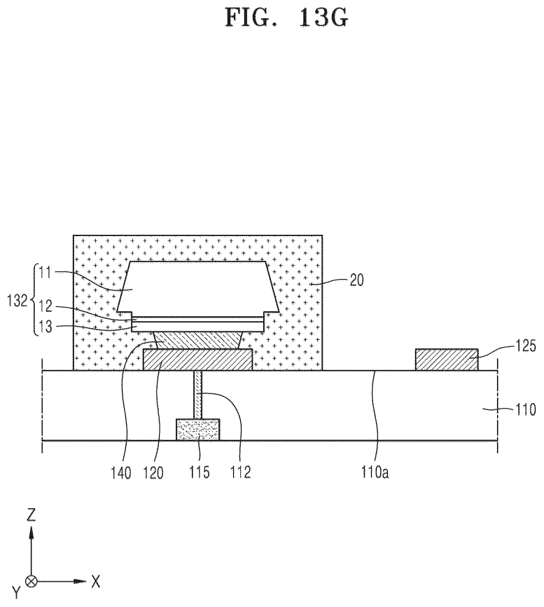

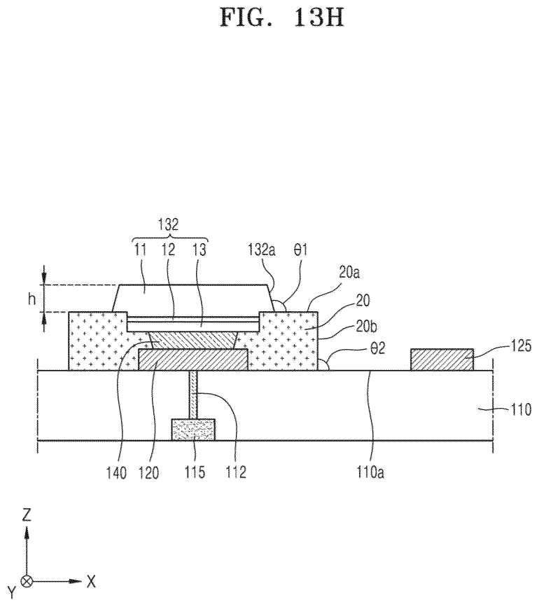

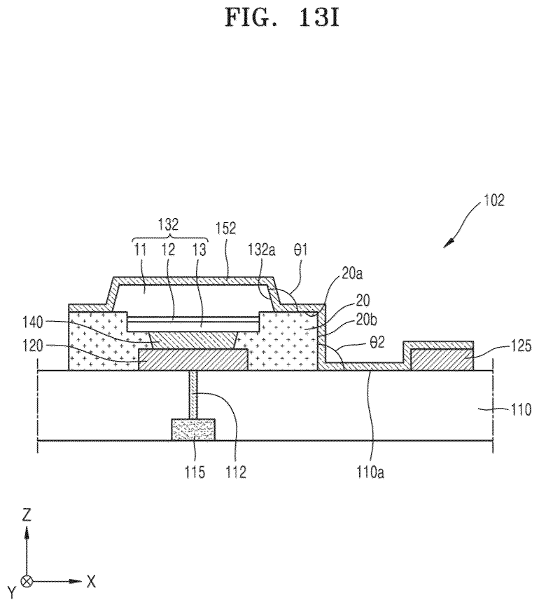

FIGS. 13A to 13I are view illustrating a method of manufacturing a display apparatus according to another embodiment.

Referring to FIG. 13A, a multilayer semiconductor layer 132 including a second-type semiconductor layer 11, an active layer 12, and a first-type semiconductor layer 13 is formed on a first substrate SU1, and a first electrode 140 is formed on the multilayer semiconductor layer 132. Thereafter, the multilayer semiconductor layer 132 is primarily etched into a shape corresponding to the first electrode 140.

In the primary etching operation, the depth of etching is adjusted such that the multilayer semiconductor layer 132 may not be completely divided into a plurality of chips, that is, the first substrate SU1 may not be exposed. For example, the depth of etching may be less than half or ⅓ of the total thickness of the multilayer semiconductor layer 132. However, embodiments are not limited thereto.

Due to a relatively small depth of etching, a lateral surface of the etched multilayer semiconductor layer 132 may be formed at an angle of about 90 degrees regardless of a mask material used in the primary etching operation.

Referring to FIG. 13B, a material layer 40 is formed to entirely cover the multilayer semiconductor layer 132 and the first electrode 140, and a second substrate SU2 is disposed on the material layer 40. The material layer 40 may include a resin material and various other films. The material layer 40 may include a material that is easily separated from the multilayer semiconductor layer 132 and the first electrode 140. That is, the material layer 40 may include a more easily releasable material.

Referring to FIG. 13C, the first substrate SU1 is separated from the multilayer semiconductor layer 132, and a surface 11a of the second-type semiconductor layer 11 is exposed.

Referring to FIG. 13D, a secondary etching operation is performed on the multilayer semiconductor layer 132. First, a mask layer 50 is formed on the second-type semiconductor layer 11. The mask layer 50 has a pattern that allows the multilayer semiconductor layer 132 to be etched into a shape corresponding to the first electrode 140. The mask layer 50 may include, for example, a photoresist material, and the angle between a lateral surface 50a of the mask layer 50 and the surface 11a of the second-type semiconductor layer 11 may be greater than about 90 degrees.

In the secondary etching operation, the depth of etching may be adjusted such that the multilayer semiconductor layer 132 may be divided into a plurality of chips, that is, the material layer 40 may be exposed. In the secondary etching operation, an etched lateral surface of the multilayer semiconductor layer 132 may have a slope similar to the slope of the lateral surface 50a of the mask layer 50. After the secondary etching operation is completed, the mask layer 50 is removed.

Referring to FIG. 13E, the angle of a lateral surface 132a of the multilayer semiconductor layer 132 is similar to the angle of the lateral surface 50a of the mask layer 50 shown in FIG. 13D. For example, the cross-sectional shape of the multilayer semiconductor layer 132 exposed above the material layer 40, that is, the cross-sectional shape in a direction parallel to a first direction (Z direction), may be adjusted such that the width of the cross-sectional shape in a second direction (X direction) perpendicular to the first direction (Z direction) may decrease in a direction away from the first electrode 140.

A micro-semiconductor chip CH including the multilayer semiconductor layer 132 and the first electrode 140 may be separated from the second substrate SU2 and transferred onto a display substrate 110 as shown in FIG. 13F.

The micro-semiconductor chip CH may be transferred by a dry transfer method such as a pick-and-place method or a wet transfer method using a liquid. When the wet transfer method is used, the transfer substrates 210 described with reference to FIGS. 8 to 12 may be used.

A first pad 120 and a second pad 125 are provided on the display substrate 110, and the first electrode 140 is bonded to the first pad 120.

Referring to FIG. 13G, an insulating layer 20 is formed to cover the first pad 120, the first electrode 140, and the multilayer semiconductor layer 132. The insulating layer 20 may include a photoresist material.

Referring to FIG. 13H, a CMP operation is performed to expose an upper surface of the multilayer semiconductor layer 132. In this case, due to the difference in CMP selectivity or hardness between the material of the multilayer semiconductor layer 132 and the material of the insulating layer 20, the material of the insulating layer 20 is polished more than the material of the multilayer semiconductor layer 132 such that the multilayer semiconductor layer 132 may be exposed and may protrude above the insulating layer 20 by, for example, a height (h). In the CMP operation, the material of the second-type semiconductor layer 11 included in the multilayer semiconductor layer 132 is also partially polished and removed. The second-type semiconductor layer 11 may include a plurality of layers having different doping concentrations, and a portion of the second-type semiconductor layer 11 removed in the CMP operation may be a portion having a relatively low doping concentration. An angle θ1 between the lateral surface 132a of the multilayer semiconductor layer 132 and an upper surface 20a of the insulating layer 20 may be greater than about 90 degrees. An angle θ2 between a lateral surface 20b of the insulating layer 20 and an upper surface 110a of the display substrate 110 may be about 90 degrees or more.

Referring to FIG. 13I, a display apparatus 102 is provided in which a second electrode 152 extends from the upper surface of the multilayer semiconductor layer 132 to the second pad 125. The second electrode 152 is in contact with the second-type semiconductor layer 11. In a process shown in FIG. 13I, a region of the second-type semiconductor layer 11 having a relatively low doping concentration may be removed, and thus, the second electrode 152 may be in contact with the second-type semiconductor layer 11 in a region having a relatively high doping concentration or a region close to the region having a relatively high doping concentration.

A material of the second electrode 152 may be formed on the lateral surface 132a of the multilayer semiconductor layer 132, and therefore, a defect rate indicating the possibility of a short circuit at the second electrode 152 may decrease.

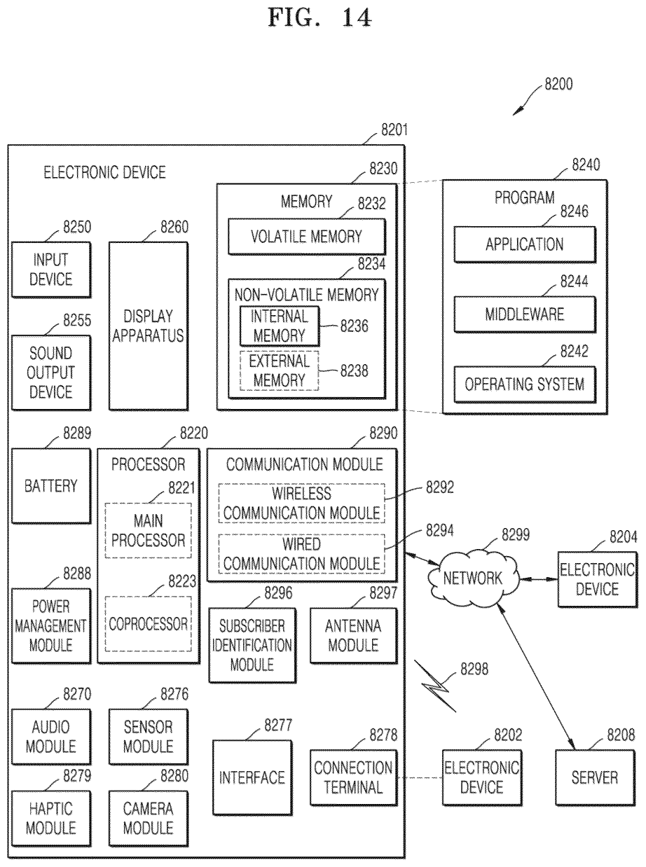

FIG. 14 is a block diagram illustrating an electronic device 8201 according to an example embodiment.

Referring to FIG. 14, the electronic device 8201 may be provided in a network environment 8200. In the network environment 8200, the electronic device 8201 may communicate with another electronic device 8202 through a first network 8298 (such as a short-range wireless communication network) or may communicate with another electronic device 8204 and/or a server 8208 through a second network 8299 (such as a long-range wireless communication network). The electronic device 8201 may communicate with the electronic device 8204 through the server 8208. The electronic device 8201 may include a processor 8220, a memory 8230, an input device 8250, a sound output device 8255, a display apparatus 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. Some of the components of the electronic device 8201 may be omitted, or other components may be added to the electronic device 8201. Some of the components may be implemented as one integrated circuit. For example, the sensor module 8276 (such as a fingerprint sensor, an iris sensor, or an illuminance sensor) may be embedded in the display apparatus 8260 (such as a display).

The processor 8220 may execute software (such as a program 8240) to control one or more other components (such as hardware or software components) of the electronic device 8201 which are connected to the processor 8220, and the processor 8220 may perform various data processing or operations. As part of data processing or computation, the processor 8220 may load commands and/or data received from other components (such as the sensor module 8276, the communication module 8290, etc.) on a volatile memory 8232, process the commands and/or data stored in the volatile memory 8232, and store resulting data in a non-volatile memory 8234. The non-volatile memory 8234 may include an internal memory 8236 and an external memory 8238. The processor 8220 may include: a main processor 8221 (such as a central processing unit, an application processor, etc.); and a coprocessor 8223 (such as a graphics processing unit, an image signal processor, a sensor hub processor, a communication processor, etc.) that may be operated independently or in conjunction with the main processor 8221. The coprocessor 8223 may consume less power than the main processor 8221 and may perform a specialized function.

The coprocessor 8223 may control functions and/or states related to some of the components (such as the display apparatus 8260, the sensor module 8276, and the communication module 8290) of the electronic device 8201, instead of the main processor 8221 while the main processor 8221 is in an inactive state (sleep mode) or together with the main processor 8221 while the main processor 8221 is in an active state (application-execution mode). The coprocessor 8223 (such as an image signal processor, a communication processor, etc.) may be implemented as part of a functionally related component (such as the camera module 8280 or the communication module 8290).

The memory 8230 may store various pieces of data required by the components (such as the processor 8220, the sensor module 8276, etc.) of the electronic device 8201. For example, the data may include: software (such as the program 8240); and instruction input data and/or output data which are related to the software. The memory 8230 may include the volatile memory 8232 and/or the non-volatile memory 8234.

The program 8240 may be stored as software in the memory 8230 and may include an operating system 8242, middleware 8244, and/or an application 8246.

The input device 8250 may receive, from outside the electronic device 8201 (for example, a user), commands and/or data to be used in the components (such as the processor 8220) of the electronic device 8201. The input device 8250 may include a remote controller, a microphone, a mouse, a keyboard, and/or a digital pen (such as a stylus pen).

The sound output device 8255 may output a sound signal to the outside of the electronic device 8201. The sound output device 8255 may include a speaker and/or a receiver. The speaker may be used for general purposes such as multimedia playback or recorded data playback, and the receiver may be used to receive incoming calls. The receiver may be integrated as a part of the speaker or may be implemented as an independent separate device.

The display apparatus 8260 may provide information to the outside of the electronic device 8201 in a visual manner. The display apparatus 8260 may include a device such as a display, a hologram device, or a projector, and a control circuit for controlling the device. The display apparatus 8260 may include one of the display apparatuses 100, 101, 102, and 103 described above, or a modified version thereof. The display apparatus 8260 may be manufactured by one of the display apparatus manufacturing methods described above or a modified version thereof. The display apparatus 8260 may include: touch circuitry configured to detect touches; and/or a sensor circuit (such as a pressure sensor) configured to measure the magnitudes of forces generated by touches.

The audio module 8270 may convert a sound into an electric signal or may conversely convert an electric signal into a sound. The audio module 8270 may acquire a sound through the input device 8250, or may output a sound through the sound output device 8255 and/or the speaker and/or headphone of another electronic device (such as the electronic device 8202) which are directly or wirelessly connected to the electronic device 8201.

The sensor module 8276 may detect an operating state (such as the power or the temperature) of the electronic device 8201 or an external environmental state (such as a user state) and may generate an electrical signal and/or a data value corresponding to the detected state. The sensor module 8276 may include a gesture sensor, a gyro sensor, a barometric pressure sensor, a magnetic sensor, an accelerometer sensor, a grip sensor, a proximity sensor, a color sensor, an infrared (IR) sensor, a biometric sensor, a temperature sensor, a humidity sensor, and/or an illumination sensor.

The interface 8277 may support one or more designated protocols that may be used by the electronic device 8201 for directly or wirelessly connection with another electronic device (such as the electronic device 8202). The interface 8277 may include a high-definition multimedia Interface (HDMI), a universal serial bus (USB) interface, a secure digital (SD) card interface, and/or an audio interface.

A connection terminal 8278 may include a connector through which the electronic device 8201 may be physically connected to another electronic device (such as the electronic device 8202). The connection terminal 8278 may include an HDMI connector, an USB connector, an SD card connector, and/or an audio connector (such as a headphone connector).

The haptic module 8279 may convert an electrical signal into a mechanical stimulus (such as vibration, movement, etc.) or an electrical stimulus that a user may perceive by the tactile or kinesthetic sense. The haptic module 8279 may include a motor, a piezoelectric element, and/or an electrical stimulation device.

The camera module 8280 may capture still images and moving images. The camera module 8280 may include a lens assembly including one or more lenses, image sensors, image signal processors, and/or flashes. The lens assembly of the camera module 8280 may collect light coming from a subject to be imaged.

The power management module 8288 may manage power supplied to the electronic device 8201. The power management module 8388 may be implemented as part of a power management integrated circuit (PMIC).

The battery 8289 may supply power to the components of the electronic device 8201. The battery 8289 may include non-rechargeable primary cells, rechargeable secondary cells, and/or fuel cells.

The communication module 8290 may support the establishment of a direct (wired) communication channel and/or a wireless communication channel between the electronic device 8201 and another electronic device (such as the electronic device 8202, the electronic device 8204, or the server 8208), and may support communication through the established communication channel. The communication module 8290 may include one or more communication processors that operate independently of the processor 8220 (such as an application processor) and support direct communication and/or wireless communication. The communication module 8290 may include: a wireless communication module 8292 (such as a cellular communication module, a short-range wireless communication module, or a global navigation satellite system (GNSS) communication module); and/or a wired communication module 8294 (such as a local area network (LAN) communication module or a power line communication module). The communication modules 8282 and 8294 may communicate with another electronic device through the first network 8298 (for example, a short-range communication network such as Bluetooth, WiFi direct, or infrared data association (IrDA)), or the second network 8299 (for example, a long-range communication network such as a cellular network, the Internet, or a computer network (LAN, WAN, etc.)). Such various types of communication modules may be integrated into one component (single chip, etc.) or may be implemented as a plurality of components (plural chips) separate from each other. The wireless communication module 8292 may identify and authenticate the electronic device 8201 in a communication network such as the first network 8298 and/or the second network 8299 by using subscriber information (such as an international mobile subscriber identifier (IMSI)) stored in the subscriber identification module 8296.

The antenna module 8297 may transmit or receive signals and/or power to or from the outside (for example, other electronic devices). An antenna may include a radiator which has a conductive pattern formed on a substrate (such as a PCB). The antenna module 8297 may include one or a plurality of such antennas. When the antenna module 8297 include a plurality of antennas, the communication module 8290 may select one of the plurality of antennas which is suitable for a communication method used in a communication network such as the first network 8298 and/or the second network 8299. Signals and/or power may be transmitted between the communication module 8290 and another electronic device through the selected antenna. In addition to the antennas, other components (such as a radio-frequency integrated circuit (RFIC)) may be included as part of the antenna module 8297.

Some of the components may be connected to each other and exchange signals (such as commands or data) by an inter-peripheral communication scheme (such as a bus, general purpose input and output (GPIO), serial peripheral interface (SPI), or mobile industry processor interface (MIPI)).

Commands or data may be transmitted between the electronic device 8201 and the (external) electronic device 8204 through the server 8208 connected to the second network 8299. The other electronic devices 8202 and 8204 and the electronic device 8201 may be the same type of electronic device or may be different types of electronic devices. All or some of operations of the electronic device 8201 may be executed in one or more of the other electronic devices 8202 and 8204, and the server 8208. For example, when the electronic device 8201 needs to perform a certain function or service, the electronic device 8201 may request one or more other electronic devices to perform a part or all of the function or service instead of performing the function or service by itself. The one or more other electronic devices receiving the request may perform an additional function or service related to the request, and may transmit results thereof to the electronic device 8201. To this end, cloud computing, distributed computing, and/or client-server computing techniques may be used.

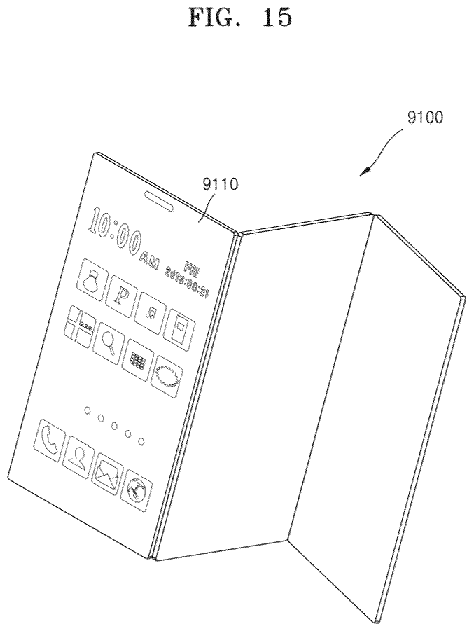

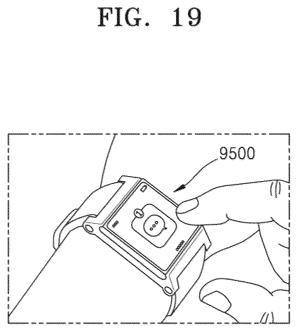

FIGS. 15 to 19 are views illustrating various electronic devices to which the display apparatuses of the example embodiments described above are applied.

FIG. 15 is a view illustrating an example in which a display apparatus 9110 is applied to a mobile device 9100 according to an example embodiment. The mobile device 9100 may include the display apparatus 9110, and the display apparatus 9110 may include one of the display apparatuses of the example embodiments described above. The display apparatus 9110 may have a foldable structure such as a multi-foldable structure.

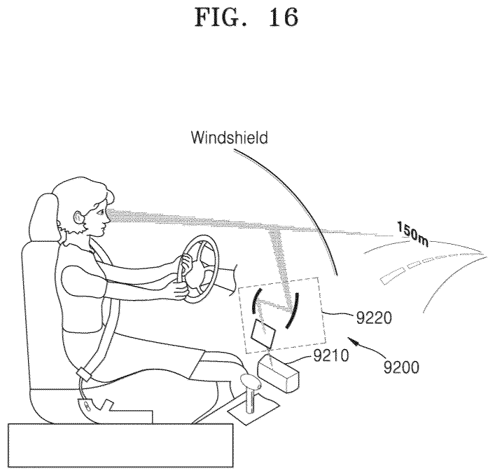

FIG. 16 is a view illustrating an example in which a display apparatus is applied to a vehicle according to an example embodiment. The display apparatus may be a vehicular head-up display apparatus 9200, and may include: a display 9210 provided in an region of the vehicle; and an optical path changing member 9220 configured to change the optical path of light such that a driver may see images generated by the display 9210.

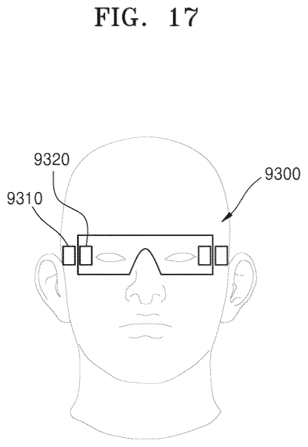

FIG. 17 is a view illustrating an example in which a display apparatus is applied to augmented reality glasses or virtual reality glasses 9300 according to an example embodiment. The augmented reality glasses 9300 may include: a projection system 9310 configured to form images; and elements 9320 configured to guide the images from projection system 9310 into the eyes of a user. The projection system 9310 may include one of the display apparatuses of the example embodiments described above.

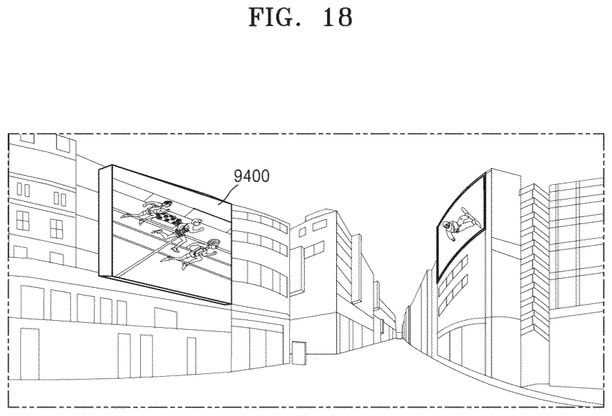

FIG. 18 is a view illustrating an example in which a display apparatus is applied to large signage 9400 according to an example embodiment. The signage 9400 may be used for outdoor advertisement using a digital information display and may control advertisement content and the like through a communication network. For example, the signage 9400 may be implemented through the electronic device 8201 described with reference to FIG. 14.

FIG. 27 is a view illustrating an example in which a display apparatus is applied to a wearable display 9500 according to an example embodiment. The wearable display 9500 may be implemented through the electronic device 8201 described with reference to FIG. 14.

The display apparatuses of the example embodiments may be applied to various products such as a rollable television (TV) and a stretchable display.

As described above, according to the one or more of the above example embodiments, the display apparatuses have a structure reducing the occurrence of defects such as electrical short circuits when micro-semiconductor chips are connected to electrode pads of display substrates.

According to the display apparatus manufacturing methods, display apparatuses may be manufactured with a relatively high productivity and a relatively low rate of defects such as electrode short circuits.

It should be understood that example embodiments described herein should be considered in a descriptive sense only and not for purposes of limitation. Descriptions of features or aspects within each example embodiment should typically be considered as available for other similar features or aspects in other embodiments. While example embodiments have been described with reference to the figures, it will be understood by those of ordinary skill in the art that various changes in form and details may be made therein without departing from the spirit and scope as defined by the following claims and their equivalents.

What is claimed is:

1. A display apparatus comprising:
a display substrate;
a first pad and a second pad on the display substrate spaced apart from each other;
a first electrode on the first pad;
a multilayer semiconductor layer comprising a first-type semiconductor layer, an active layer, and a second-type semiconductor layer that are sequentially on the first electrode in a first direction;
an insulating layer on the display substrate and adjacent to the first pad, the first electrode, and the multilayer semiconductor layer, a height of an upper surface of the insulating layer being lower than an upper surface of the multilayer semiconductor layer; and
a second electrode on an upper surface of the multilayer semiconductor layer, an exposed lateral surface of the multilayer semiconductor layer, and a surface of the insulating layer, the second electrode connecting the second-type semiconductor layer and the second pad to each other,
wherein an angle between the exposed lateral surface of the multilayer semiconductor layer and an upper surface of the insulating layer is greater than or equal to 90 degrees.

2. The display apparatus of claim 1, wherein the angle between the exposed lateral surface of the multilayer semiconductor layer and the upper surface of the insulating layer is 90 degrees.

3. The display apparatus of claim 2, wherein a width of the multilayer semiconductor layer in a second direction perpendicular to the first direction is constant.

4. The display apparatus of claim 1, wherein the angle between the exposed lateral surface of the multilayer semiconductor layer and the upper surface of the insulating layer is greater than 90 degrees.

5. The display apparatus of claim 4, wherein the multilayer semiconductor layer comprises a first portion adjacent to the insulating layer and a second portion exposed from the insulating layer, and
wherein a width of the first portion of the multilayer semiconductor layer and a width of the second portion of the multilayer semiconductor layer in a second direction perpendicular to the first direction varies.

6. The display apparatus of claim 1, wherein an angle between a lateral surface of the insulating layer and an upper surface of the display substrate is greater than or equal to 90 degrees.

7. The display apparatus of claim 1, further comprising a driving device in the display substrate and electrically connected to the first electrode.

8. The display apparatus of claim 1, further comprising a color conversion layer on the multilayer semiconductor layer, the color conversion layer being configured to convert a color of light emitted from the multilayer semiconductor layer.

9. A method of manufacturing a display apparatus, the method comprising:
forming a multilayer semiconductor layer on a first substrate, the multilayer semiconductor layer comprising a first-type semiconductor layer, an active layer, and a second-type semiconductor layer that are sequentially stacked in a first direction;
forming a first electrode on the multilayer semiconductor layer;
forming a micro-semiconductor chip by etching the multilayer semiconductor layer to correspond to the first electrode such that a width of the micro-semiconductor chip in a second direction perpendicular to the first direction is constant or decreases in the first direction away from the first electrode;
transferring the micro-semiconductor chip onto a display substrate that comprises a first pad and a second pad such that the first electrode and the first pad contact each other;
forming an insulating layer on the display substrate to a height such that the insulating layer is adjacent to the first pad, the first electrode, and the multilayer semiconductor layer an exposes an upper portion of the multilayer semiconductor layer; and
forming a second electrode on an upper surface of the multilayer semiconductor layer, an exposed lateral surface of the multilayer semiconductor layer, and a surface of the insulating layer, the second electrode connecting the second-type semiconductor layer and the second pad to each other.

10. The method of claim 9, wherein the forming of the micro-semiconductor chip comprises:
a primary etching operation of the multilayer semiconductor layer such that a width of the multilayer semiconductor layer in a second direction perpendicular to the first direction increases in a direction away from the first electrode; and
a secondary etching operation of the multilayer semiconductor layer such that the multilayer semiconductor layer has a constant width in the second direction perpendicular to the first direction.

11. The method of claim 10, wherein the primary etching operation comprises a dry etching method, and the secondary etching operation comprises a wet etching method.

12. The method of claim 9, wherein the forming of the micro-semiconductor chip is performed by a dry etching method based on a hard mask layer such that a width of the multilayer semiconductor layer in a second direction perpendicular to the first direction is constant.

13. The method of claim 9, wherein the forming of the micro-semiconductor chip comprises:
primarily etching the multilayer semiconductor layer to a depth in the first direction at which the first substrate is not exposed;
forming a material layer entirely on the multilayer semiconductor layer and the first electrode;
placing a second substrate on the material layer and separating the first substrate from the multilayer semiconductor layer such that a surface of the multilayer semiconductor layer is separated from the first substrate and is exposed;
secondarily etching the multilayer semiconductor layer from the surface of the multilayer semiconductor layer to expose the material layer; and
removing the material layer.

14. The method of claim 13, wherein the secondary etching is performed such that the multilayer semiconductor layer exposed above the material layer has a width in a second direction perpendicular to the first direction that decreases in the first direction away from the first electrode.

15. The method of claim 9, wherein the forming of the insulating layer comprises forming the insulation layer such that an angle between a lateral surface of the insulating layer and an upper surface of the display substrate is 90 degrees or more.

16. The method of claim 9, wherein the transferring of the micro-semiconductor chip comprises a fluid self-alignment transfer.

17. The method of claim 16, wherein the transferring of the micro-semiconductor chip comprises transferring the micro-semiconductor chip to a transfer substrate comprising a plurality of grooves.

18. The method of claim 17, wherein the plurality of grooves form a plurality of groups, each of the plurality of groups comprising one or more adjacent grooves, and the plurality of groups being regularly arranged.

19. The method of claim 9, wherein the forming of the insulating layer comprises forming the insulating layer entirely on the first pad, the first electrode, and the multilayer semiconductor layer, and polishing an upper portion of the insulating layer to expose the upper portion of the multilayer semiconductor layer.

20. The method of claim 19, wherein, the polishing of the upper portion of the insulating layer comprises removing a portion of the second-type semiconductor layer of the multilayer semiconductor layer.
